(19) United States
(12) Patent Application Publication
(10) Pub. No.: US 2018/0122693 A1
(43) Pub. Date: May 3, 2018

(54) METHOD FOR FORMING SEMICONDUCTOR STRUCTURE

(71) Applicant: UNITED MICROELECTRONICS CORP., Hsinchu (TW)

(72) Inventors: Wen-Yu Yang, Pingtung City (TW); Chien-Hua Shih, Tainan City (TW); Hsin-Yi Chung, Kaohsiung City (TW); Shu-Hui Hu, Tainan City (TW)

(21) Appl. No.: 15/342,290

(22) Filed: Nov. 3, 2016

(51) Int. Cl. H01L 21/768; H01L 21/311; H01L 21/02

(52) U.S. Cl. CPC H01L 21/76837; H01L 21/31105; H01L 29/423; H01L 21/02164; H01L 21/02315

(57) ABSTRACT

A method for forming a semiconductor structure is provided, including the following steps. A first dielectric layer is formed on a substrate. An etching step is performed to the first dielectric layer. A N₂O treating step is performed to an etched surface of the first dielectric layer. A second dielectric layer is formed on a N₂O treated surface of the first dielectric layer.

### BACKGROUND

### Technical Field

The disclosure relates to a method for forming a semiconductor structure, and more particularly to a method for forming a semiconductor structure comprising a dielectric film.

### Description of the Related Art

Size of semiconductor device has been decreased for these years. Reduction of feature size, improvements of the speed, the efficiency, the density and the cost per integrated circuit unit are the important goals in the semiconductor technology. The electrical properties of the device have to be maintained even improved with the decrease of the size, to meet the requirements of the commercial products in applications. For example, the layers and components with damages, which have considerable effects on the electrical performance, would be one of the important issues of the device for the manufacturers. Generally, a semiconductor device with good electrical performance requires the elements with complete profiles.

### SUMMARY

According to an embodiment, a method for forming a semiconductor structure is provided, comprising the following steps. A first dielectric layer is formed on a substrate. An etching step is performed to the first dielectric layer. A N₂O treating step is performed to an etched surface of the first dielectric layer. A second dielectric layer is formed on a N₂O treated surface of the first dielectric layer.

### BRIEF DESCRIPTION OF THE DRAWINGS

FIGS. 1-4 illustrate a method for forming a semiconductor structure according to an embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

According to embodiments, a first (lower) dielectric layer is etched and then an etched surface of the first dielectric layer is treated with N₂O so that a second (upper) dielectric layer formed on a treated surface of the first dielectric layer can be deposited with a steady rate.

Embodiments are provided hereinafter with reference to the accompanying drawings for describing the related procedures and configurations. It is noted that not all embodiments of the invention are shown. The identical and/or similar elements of the embodiments are designated with the same and/or similar reference numerals. Also, it is noted that there may be other embodiments of the present disclosure which are not specifically illustrated. Modifications and variations can be made without departing from the spirit of the disclosure to meet the requirements of the practical applications. It is also important to point out that the illustrations may not be necessarily be drawn to scale. Thus, the specification and the drawings are to be regard as an illustrative sense rather than a restrictive sense.

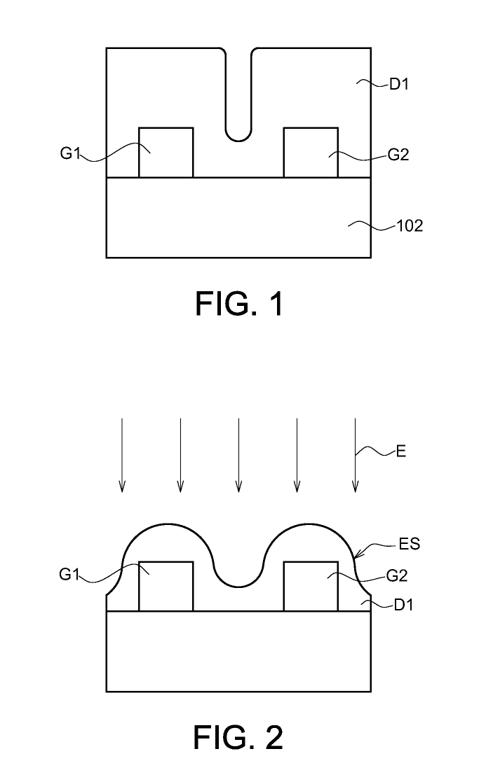

FIGS. 1-4 illustrate a method for forming a semiconductor structure according to an embodiment.

Referring to FIG. 1, a gate structure G1 and a gate structure G2 may be formed on a substrate 102. A first dielectric layer D1 may be formed on the substrate 102, the gate structure G1 and the gate structure G2.

In embodiments, the first dielectric layer D1 contains silicon. In an embodiment, the first dielectric layer D1 may contain silicon and oxide. For example, the first dielectric layer D1 may comprise silicon oxide, such as a spin-on glass (SOG), SiO₂, SiOₓ, or other suitable materials.

The first dielectric layer D1 may be formed by a method comprising a plasma deposition method, a thermal deposition method or other suitable methods. For example, the plasma deposition method may comprise a plasma-enhanced chemical vapor deposition (PECVD) method, or other suitable methods. In an embodiment, for example, the first dielectric layer D1 is formed by a method comprising a thermal deposition method without using a plasma. For example, the thermal deposition method may comprise a sub-atmospheric chemical vapor deposition (SACVD) method.

Referring to FIG. 2, an etching step E is performed to the first dielectric layer D1 to form an etched surface ES of the first dielectric layer D1. In embodiments, the etching step E uses a fluorine containing etchant, for example comprising fluorocarbons such as CF₄, SF₆, NF₃, or other suitable compounds, or a combination thereof. The etching step E may comprise an anisotropic etching method. The etching step E may comprise a dry etching method or a wet etching method. In an embodiment, for example, the etching step E may comprise a plasma etching process using a gas as a plasma source comprising a fluorine containing gas, for example comprising fluorocarbons such as CF₄, SF₆, NF₃, or other suitable gases, or a combination thereof.

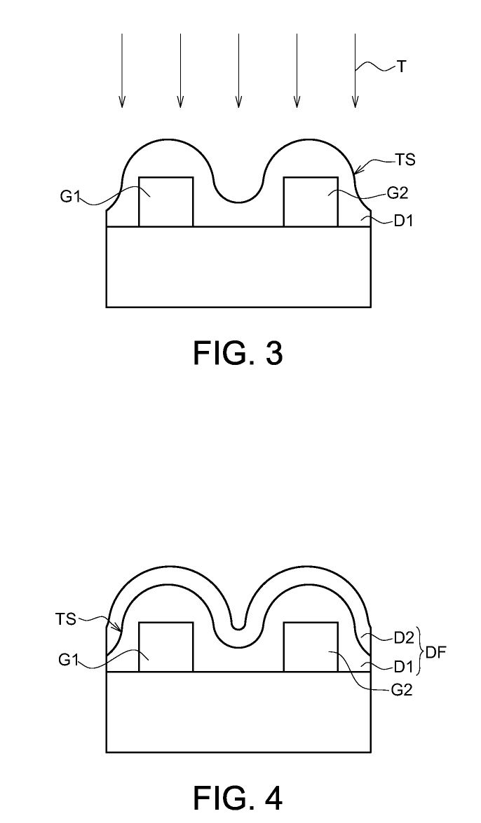

Referring to FIG. 3, a N₂O treating step T is performed to the etched surface ES of the first dielectric layer D1 as illustrated with FIG. 2 to form a N₂O treated surface TS of the first dielectric layer D1. In embodiments, the N₂O may help eliminating the remainder generated from the etching step E that would affect a subsequently formed second dielectric layer D2 (FIG. 4). For example, the remainder may comprise a fluorine atom from the fluorine containing etchant bonding to a hydrogen atom or bonding to an oxygen atom of the silicon oxide contained by the first dielectric layer D1. The N₂O treating step T may comprise a N₂O plasma process, for example using a gas comprising a N₂O gas as a plasma source. The gas for the plasma process may comprise other suitable kinds of gases.

In an embodiment, the etching step E as illustrated with FIG. 2 and the N₂O treating step T as illustrated with FIG. 3 are ex-situ processes. For example, after the etching step E, a wafer may be transferred from an etching chamber into a front opening unified pod (FOUP), stayed in the FOUP for a waiting time, and then transferred from the FOUP into a chamber for performing the N₂O treating step T at a suitable timing.

Referring to FIG. 4, the second dielectric layer D2 is formed on a N₂O treated surface TS of the first dielectric layer D1 formed by the N₂O treating step T as illustrated with FIG. 3. The second dielectric layer D2 may contain silicon. In an embodiment, the second dielectric layer D2 may contain silicon and oxide. For example, the second dielectric layer D2 may comprise silicon oxide, such as a spin-on glass (SOG), SiO₂, SiOₓ, or other suitable materials.

The second dielectric layer D2 may be formed by a method comprising a plasma deposition method or a thermal deposition method, or other suitable methods. For example, the plasma deposition method may comprise a plasma-enhanced chemical vapor deposition (PECVD) method, or other suitable methods. In an embodiment, for example, the second dielectric layer D2 is formed by a method comprising a thermal deposition method without using a plasma. For example, the thermal deposition method may comprise a sub-atmospheric chemical vapor deposition (SACVD) method.

As shown in FIG. 4, the first dielectric layer D1 and the second dielectric layer D2 form a dielectric film DF filling a gap between the gate structure G1 and the gate structure G2 and on the gate structures G1, G2.

In embodiments, there is the N₂O treating step T performed to the etched surface ES of the first dielectric layer D1 (lower dielectric layer). Therefore, a deposition rate of the second dielectric layer D2 (upper dielectric layer) formed on the N₂O treated surface TS of the first dielectric layer D1 is stable regardless of a waiting time from finishing the etching step E to beginning a process of forming the second dielectric layer D2.

In a comparative example, there is no N₂O treating step T performed to an etched surface ES of the first dielectric layer D1. In other words, the step illustrated with FIG. 3 is omitted. It results in an unstable deposition rate to the second dielectric layer D2 formed on the etched surface ES of the first dielectric layer D1. In particular, the deposition rate of the second dielectric layer D2 becomes lower as a waiting time from finishing the etching step E to beginning a process of forming the second dielectric layer D2 is longer. In addition, defects such as seam defect, voids, (W) bridge occur in a dielectric film for filling the gap between gate structures G1, G2 in the comparative example.

Contrary to the comparative example, the method according to the concepts of embodiments of the present application can avoid the deposition rate shift issue to the second dielectric layer D2. The method according to the concepts of embodiments of the present application can avoid the defects such as seam defect, voids, (W) bridge when being applied for forming the dielectric film DF for filling the gap between gate structures G1 and G2 and on the gate structures G1, G2.

The concepts of the disclosed method are not limited to the dielectric film DF formed by the first dielectric layer D1 and the second dielectric layer D2. A dielectric film being a multilayer structure of more than two dielectric layers may be used. In an embodiment, for example, the second dielectric layer D2 (regarded as a lower dielectric layer in this case) may be etched and then an etched surface of the second dielectric layer D2 may be treated with another N₂O treating step, and then a third dielectric layer dielectric layer (not shown, regarded as an upper dielectric layer) may be formed on a N₂O treated surface of the second dielectric layer D2, and so forth.

In an embodiment, the steps as illustrated with FIG. 1 to FIG. 4 may be ex-situ processes. In an embodiment, a CMP process may be performed to a top surface of the dielectric film DF to obtain a planar top surface facilitating other elements formed therein or thereon, such as a conductive plug, an inter-layer dielectric film, etc.

According the foregoing disclosure, the method according to the concepts of embodiments of the present application can obtain a stable deposition rate to the second (upper) dielectric layer formed on the first (lower) dielectric layer. The method according to the concepts of embodiments of the present application can prevent the dielectric film for filling the gap between the gate structures from the defect that would result in an un-expected short.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A method for forming a semiconductor structure, comprising:
forming a first dielectric layer on a substrate;
performing an etching step to the first dielectric layer, wherein the etching step uses a fluorine containing etchant;
performing a N₂O treating step to an etched surface of the first dielectric layer; and
forming a second dielectric layer on a N₂O treated surface of the first dielectric layer.

2. The method for forming the semiconductor structure according to claim 1, wherein the first dielectric layer contains silicon.

3. The method for forming the semiconductor structure according to claim 1, wherein the first dielectric layer contains silicon and oxide.

4. The method for forming the semiconductor structure according to claim 1, wherein the first dielectric layer comprises silicon oxide.

5. The method for forming the semiconductor structure according to claim 1, wherein the first dielectric layer is formed by a method comprising a plasma deposition method or a thermal deposition method.

6. The method for forming the semiconductor structure according to claim 1, wherein the first dielectric layer is formed by the method comprising the thermal deposition method without using a plasma.

7. (canceled)

8. The method for forming the semiconductor structure according to claim 1, wherein the fluorine containing etchant comprises CF₄, SF₆, NF₃.

9. The method for forming the semiconductor structure according to claim 1, wherein the etching step comprises an anisotropic etching method.

10. The method for forming the semiconductor structure according to claim 1, wherein the etching step comprises a dry etching method or a wet etching method.

11. The method for forming the semiconductor structure according to claim 10, wherein the etching step comprises the dry etching method.

12. The method for forming the semiconductor structure according to claim 1, wherein the N₂O treating step comprises a N₂O plasma process.

13. The method for forming the semiconductor structure according to claim 1, wherein the etching step and the N₂O treating step are ex-situ processes.

14. The method for forming the semiconductor structure according to claim 1, wherein the second dielectric layer contains silicon.

15. The method for forming the semiconductor structure according to claim 1, wherein the second dielectric layer contains silicon and oxide.

16. The method for forming the semiconductor structure according to claim 1, wherein the second dielectric layer comprises silicon oxide.

17. The method for forming the semiconductor structure according to claim 1, wherein the second dielectric layer is formed by a method comprising a plasma deposition method or a thermal deposition method.

18. The method for forming the semiconductor structure according to claim 1, wherein the second dielectric layer is formed by the method comprising the thermal deposition method without using a plasma.

19. The method for forming the semiconductor structure according to claim 1, further comprising forming gate structures on the substrate.

20. The method for forming the semiconductor structure according to claim 19, wherein the first dielectric layer and the second dielectric layer form a dielectric film filling a gap between the gate structures and on the gate structures.
